(19) United States
(12) Patent Application Publication
(10) Pub. No.: US 2024/0383634 A1
(43) Pub. Date: Nov. 21, 2024

(54) PACKAGING TRAY

(71) Applicant: Japan Display Inc., Tokyo (JP)

(72) Inventors: Youhei IWAI, Tokyo (JP); Kazuhiro KIMOTO, Tokyo (JP)

(21) Appl. No.: 18/664,421

(22) Filed: May 15, 2024

(30) Foreign Application Priority Data
May 19, 2023 (JP) 2023-083270

(51) Int. Cl. B65D 1/34; B65D 25/10; B65D 81/05; B65D 85/48

(52) U.S. Cl. CPC B65D 1/34; B65D 25/108; B65D 81/05; B65D 85/48; B65D 2585/6835

(57) ABSTRACT

A packaging tray includes: a housing part housing a flat-plate-shaped member to be housed, including a glass plate member; a holding part covering the member to be housed and the housing part to hold the member to be housed in a direction different from a direction of the housing part; and a plurality of holding protrusions provided in the holding part, protruding toward the housing part, and each extending along a side surface of the member to be housed in an extension direction in which the side surface extends. The holding protrusion includes: a first region between a holding end surface that is an end surface and a center in the extension direction and a second region different from the first region. A shape of the holding protrusion in the first region differs from a shape of the holding protrusion in the second region.

### CROSS-REFERENCE TO RELATED APPLICATION

The present application claims priority to Japanese Patent Application No. 2023-83270 filed on May 19, 2023, the disclosure of which is incorporated herein by reference.

### TECHNICAL FIELD OF THE INVENTION

The present invention relates to a packaging tray.

### BACKGROUND OF THE INVENTION

When a flat-plate-shaped object such as a liquid crystal display panel is conveyed, a packaging tray is used. Japanese Patent Application Laid-Open Publication No. 2008-100743 (Patent 1)) discloses a packaging tray provided with a Document peripheral side portion that holds an object to be housed as the flat-plate-shaped object and prevents the object from dropping off. The peripheral side portion is provided with a taper-shaped protrusion that is inclined toward the upper surface side. When the object to be housed comes into contact with a taper surface of the protrusion, the object to be housed is positioned and housed in the packaging tray. The objects to be housed are conveyed in a state in which a plurality of packaging trays each housing the object to be housed therein overlap one another.

### SUMMARY OF THE INVENTION

However, there is a problem that the object to be housed that is packaged in the packaging tray is damaged by a vibration and a collision to be applied to the packaging tray during conveyance.

An aspect of the present invention is a packaging tray including: a housing part housing a flat-plate-shaped member to be housed, including a glass plate member; a holding part covering the member to be housed and the housing part to hold the member to be housed in a direction different from a direction of the housing part; and a plurality of protrusions provided in the holding part, protruding toward the housing part, and each extending along a side surface of the member to be housed in an extension direction in which the side surface extends. The protrusion includes a first region between its end surface and center in the extension direction and a second region different from the first region. A shape of the protrusion in the first region differs from a shape of the protrusion in the second region.

Another aspect of the present invention is a packaging tray including: a housing part housing a flat-plate-shaped member to be housed, including a glass plate member; a holding part covering the member to be housed and the housing part to hold the member to be housed in a direction different from a direction of the housing part; and a plurality of protrusions provided in the holding part, protruding toward the housing part, and each extending along a side surface of the member to be housed in an extension direction in which the side surface extends. The protrusion includes a first region between its end surface and center in the extension direction and a second region different from the first region. The protrusion in the first region has a lower rigidity than a rigidity of the protrusion in the second region.

Another aspect of the present invention is a packaging tray including: a housing part housing a flat-plate-shaped member to be housed, including a glass plate member; a holding part covering the member to be housed and the housing part to hold the member to be housed in a direction different from a direction of the housing part; and a protrusion provided in the holding part, protruding toward the housing part, and surrounding an entire range of outer peripheries of the side surfaces of the member to be housed. The protrusion has a taper-shaped holding side surface holding the member to be housed while coming into contact with the side surface of the member to be housed.

### BRIEF DESCRIPTIONS OF THE DRAWINGS

FIG. 1 is an exterior view of a packaging tray according to a first embodiment;

FIG. 2 is a cross-sectional view of the packaging tray;

FIGS. 3A and 3B are exterior views of a holding part in the packaging tray according to the first embodiment;

FIGS. 4A and 4B are cross-sectional views of the holding part in the packaging tray according to the first embodiment;

FIG. 5 is an exterior view of a holding part in a packaging tray according to a second embodiment;

FIG. 6 is an exterior view of a holding part in a packaging tray according to a third embodiment;

FIGS. 7A to 7C are cross-sectional views of the holding part in the packaging tray according to the third embodiment;

FIG. 8 is an exterior view of a holding part in a packaging tray according to a fourth embodiment;

FIGS. 9A and 9B are exterior views of a holding part in a packaging tray according to a fifth embodiment;

FIGS. 10A and 10B are exterior views of a holding part in a packaging tray according to a sixth embodiment;

FIGS. 11A and 11B are exterior views of a holding part in a packaging tray according to a seventh embodiment; and

FIG. 12 is an exterior view of a holding part in a packaging tray according to an eighth embodiment.

### DESCRIPTIONS OF THE PREFERRED EMBODIMENTS

The following is explanation for each embodiment of the present invention with reference to drawings. Note that only one example is disclosed, and appropriate modification with keeping the idea of the present invention which can be anticipated by those who are skilled in the art is obviously within the scope of the present invention. Also, in order to make the explanation clear, a width, a thickness, a shape, and others of each portion in the drawings are schematically illustrated more than those in an actual aspect in some cases. However, the illustration is only an example, and does not limit the interpretation of the present invention. In the present specification and each drawing, similar elements to those described earlier for the already-described drawings are denoted with the same reference characters, and detailed explanation for them is appropriately omitted in some cases.

### First Embodiment

A packaging tray according to a first embodiment will be described below with reference to the drawings. The packaging tray is used during a working process or others of housing and conveying a flat-plate-shaped product including a glass plate member as a member to be housed, the glass plate member being, for example, a cover glass, a liquid crystal panel, a backplane substrate, a TFT (thin film transistor) substrate used for liquid crystal display, a plate-shaped glass substrate used for an X-ray sensor board or the like, a glass single plate or others. Specifically, the member to be housed including the rectangular flat-plate-shaped glass plate member is conveyed together with the packaging tray while being housed in the packaging tray.

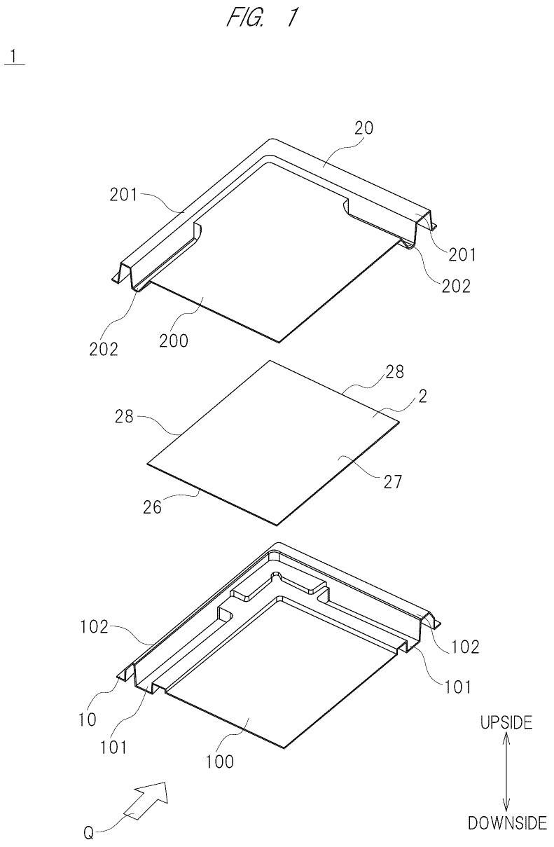

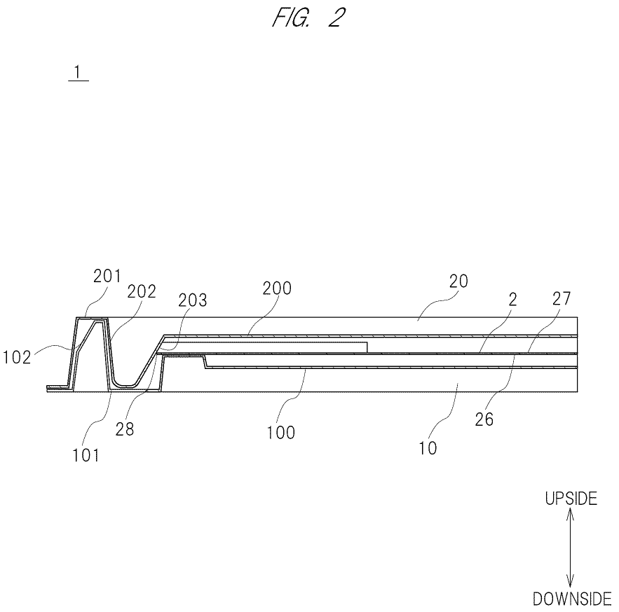

FIG. 1 is a perspective view illustrating an enlarged part of member to be housed 2 and a packaging tray 1 housing the member to be housed 2 in the first embodiment to be enlarged. FIG. 2 is a cross-sectional view in view of a state in which the member to be housed 2 is housed in the packaging tray 1, in a direction indicated by an arrow Q in FIG. 1. Note that FIGS. 1 and 2 respectively illustrate the enlarged vicinity of one of four corner portions of the member to be housed 2 and the packaging tray 1 having the rectangular plate shape.

The packaging tray 1 includes a housing part 10 and a holding part 20. The housing part 10 is a tray made of, for example, a resin material on which the member to be housed 2 is placed. The holding part 20 is a tray made of, for example, a resin material which covers the member to be housed 2 and the housing part 10 that houses the member to be housed 2. In the following description, a side provided with the housing part 10 may be referred to as lower side, and a side provided with the holding part 20 may be referred to as upper side.

### <Housing Part 10>

The housing part 10 holds the member to be housed 2 from the lower side. The housing part 10 includes a holding bottom surface 100, an attachment recess 101, and an attachment protrusion 102. The holding bottom surface 100 is a surface facing a lower-side surface (lower surface) 26 of the member to be housed 2 when the member to be housed 2 is placed thereon. The attachment recess 101 protrudes in an opposite direction (i.e., downward) to a direction in which the member to be housed 2 is placed on the holding bottom surface 100. The attachment recess 101 is formed on the outer periphery of each of four side surfaces 28 of the rectangular-flat-plate-shaped member to be housed 2 placed on the holding bottom surface 100, and extends in an extension direction in which each of the side surfaces 28 of the member to be housed 2 extends. In the extension direction, note that a length of the attachment recess 101 is smaller than a length of the side surface 28 of the member to be housed 2. The member to be housed 2 is placed in a region R on the holding bottom surface 100 surrounded by the plurality of attachment recesses 101. The attachment protrusion 102 is formed on the outer periphery of the attachment recess 101, and protrudes upward with respect to the holding bottom surface 100.

### <Holding Part 20>

The holding part 20 covers the member to be housed 2 and the housing part 10 from the upper side when being arranged above the member to be housed 2 and the housing part 10 that houses the member to be housed 2. Therefore, the holding part 20 holds the member to be housed 2 in a different direction from that of the housing part 10. The holding part 20 includes a holding bottom surface 200, a holding recess 201, and a holding protrusion 202. The holding bottom surface 200 is a surface facing an upper-side surface (upper surface) 27 of the member to be housed 2 when the holding part 20 is arranged above the member to be housed 2 and the housing part 10.

### <Holding Recess 201>

The holding recess 201 protrudes in an opposite direction (i.e., upward) to a direction facing the housing part 10 and the member to be housed 2 with respect to the holding bottom surface 200 when being arranged above the housing part 10. Accordingly, the holding recess 201 is recessed upward when the holding part 20 is viewed from the lower surface. The holding recess 201 is formed at a position corresponding to a position of formation of the attachment protrusion 102 of the housing part 10. That is, the holding recess 201 is formed along an entire region on the outer periphery of the holding part 20. Accordingly, when the holding part 20 is arranged above the housing part 10, the attachment protrusion 102 of the housing part 10 is housed in the holding recess 201 of the holding part 20 as illustrated in FIG. 2.

Note that FIG. 1 illustrates a case where the attachment protrusion 102 is formed along the entire region on the outer periphery of the housing part 10 while the holding recess 201 is formed along the entire region on the outer periphery of the holding part 20. However, the attachment protrusion 102 may be formed in part on the outer periphery of the housing part 10 while the holding recess 201 may be formed in part on the outer periphery of the holding part 20.

### <Holding Protrusion 202>

The holding protrusion 202 is a protrusion that protrudes downward toward the hosing part 10 and the member to be housed 2 with respect to the holding bottom surface 200 when being arranged above the housing part 10. The holding protrusion 202 is formed at a position corresponding to a position of formation of the attachment recess 101 of the housing part 10. Specifically, the holding protrusion 202 is formed on the outer periphery of each of the four side surfaces 28 of the rectangular-flat-plate-shaped member to be housed 2, and extends in an extension direction in which each side surface of the member to be housed 2 extends. That is, the holding part 20 is provided with the plurality of holding protrusions 202. A length of extension of the holding protrusion 202 in the extension direction is equal to or smaller than a length of extension of the attachment recess 101 of the housing part 10 in the extension direction. Therefore, when the holding part 20 is arranged above the housing part 10, the holding protrusion 202 is housed in the attachment recess 101 of the housing part 10.

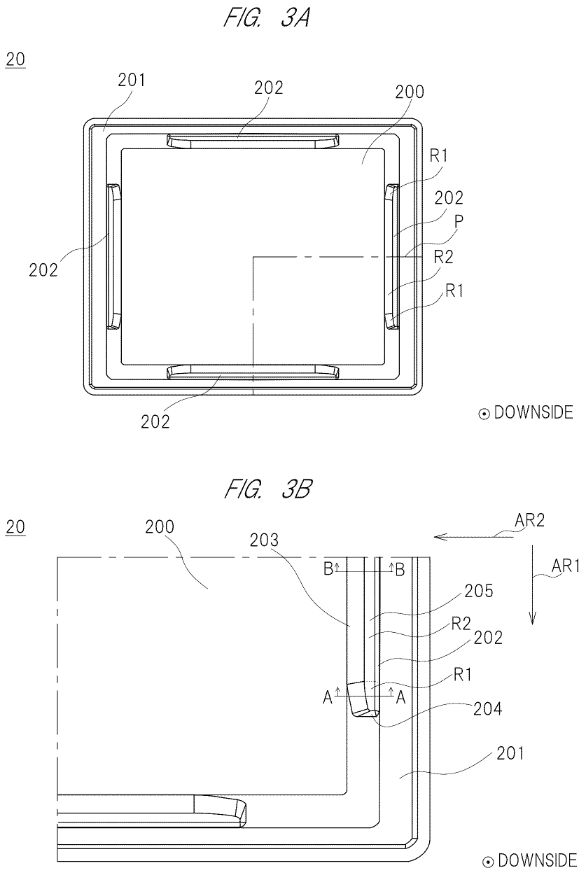

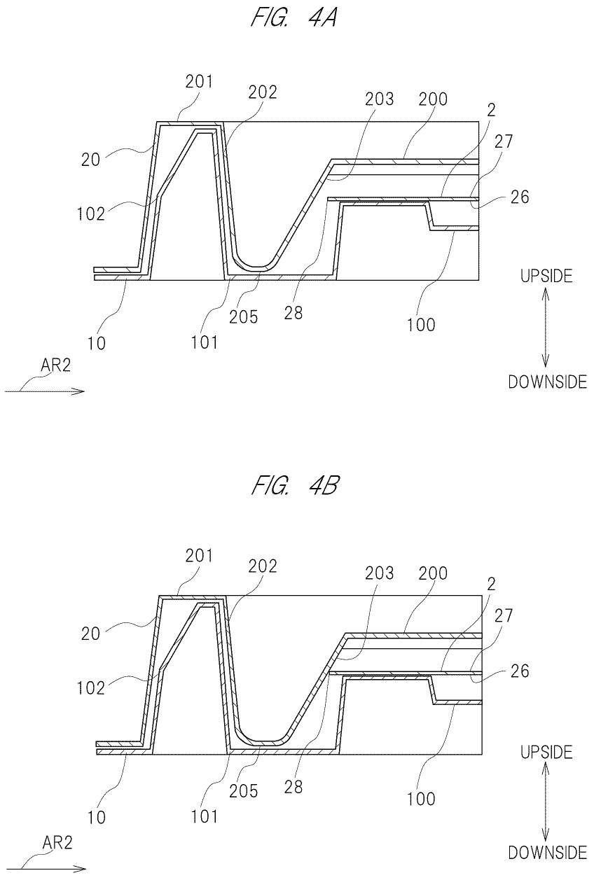

The holding protrusion 202 will be described in detail below. FIG. 2 is an exterior view on the lower surface side of the holding part 20, FIG. 3A illustrates the entire holding part 20, and FIG. 3B illustrates a range P illustrated in FIG. 3A to be enlarged. FIG. 4 is each cross-sectional view of the holding part 20, FIG. 4A is a cross-sectional view taken along a line A-A illustrated in FIG. 3B, and FIG. 4B is a cross-sectional view taken along a line B-B illustrated in FIG. 3B. Note that FIG. 4 illustrates combination of the housing part 10 in which the holding part 20 is arranged and the member to be housed 2 that is housed in the housing part 10. FIG. 3A illustrates a case where the holding protrusions 202 are respectively formed on the outer peripheries of the four side surfaces 28 of the member to be housed 2. However, the plurality of holding protrusions 202 may be formed on the outer periphery of each of the four side surfaces 28 in accordance with the respective lengths of the four side surfaces 28 of the member to be housed 2.

The holding protrusion 202 includes a holding side surface 203, a holding end surfaces 204, and a holding top 205. The holding side surface 203 is a side surface of the holding protrusion 202 that connects with the holding bottom surface 200 and is formed into a taper shape having an inclination that is not in parallel to an up-down direction. Accordingly, the holding side surface 203 also has a long side along an extension direction AR1 in which the holding protrusion 202 extends. The holding side surface 203 is a surface facing the side surface 28 of the member to be housed 2 that is housed in the housing part 10. When getting closer to the upper side, the taper shape of the holding protrusion 202 more protrudes toward the side surface 28 of the member to be housed 2 in an intersection direction AR2 intersecting the extension direction AR1. Accordingly, the holding part 20 is arranged above the housing part 10 in a state in which the holding side surface 203 is contactable with an edge portion at which an upper end of the side surface 28 of the member to be housed 2 and the upper surface 27 connect with each other (see FIG. 4B). That is, the arrangement of the holding part 20 above the housing part 10 causes either a state in which the holding side surface 203 comes into contact with the edge portion of the member to be housed 2 or a state in which the holding side surface 203 does not come into contact with the edge portion of the member to be housed 2 to form a gap.

The holding end surface 204 is a surface connecting with the holding bottom surface 200 and an end portion of the holding side surface 203 in the extension direction AR1. The holding top 205 is a surface connecting with a lower-side end portion of the holding side surface 203 and a lower-side end portion of the holding end surface 204.

As illustrated in FIGS. 3A and 3B, the holding protrusion 202 includes a first region R1 including both end portions in the extension direction AR1 and a second region R2 different from the first region R1. Specifically, the first region R1 is a region between the center and the holding end surface 204 as the end surface in the extension direction AR1. The second region R2 is a region including the center in the extension direction AR1. A shape of the holding protrusion 202 in the first region R1 differs from a shape of the holding protrusion 202 in the second region R2.

Specifically, a side of the holding top 205 of the holding protrusion 202 in the first region R1, the side facing the side surface 28 of the member to be housed 2, is not in parallel to the extension direction AR1 so that the holding top 205 is formed into a circular arc shape toward the outer periphery of the holding part 20. That is, the holding top 205 in the first region R1 is formed into a shape bringing it to be away from the side surface 28 of the member to be housed 2. More particularly, a gap distance of the holding top 205 in the first region R1 away from the side surface 28 of the member to be housed 2 is larger when getting closer to the end portion (the holding end surface 204) in the extension direction AR1. Note that a value of a curve radius of the circular arc portion of the holding top 205 and a value of a range of the first region R1 may take appropriately preferable values depending on the length of the holding protrusion 202 in the extension direction AR1, the size of the member to be housed 2, or the like. For example, the holding top 205 in the first region R1 is formed into a gentle circular arc shape, at least a part of which has a curve radius of 300 mm to 900 mm. In the present first embodiment, a value of the curve radius is, for example, nearly 600 mm. On the other hand, in a comparative example with a holding top having a shape not bringing it to be away from the side surface of the member to be housed 2, the value of the curve radius of the holding top in the vicinity of the holding end surface is nearly 20 mm to 30 mm. Thus, it can be said that the holding protrusion 202 of the first embodiment includes the holding top 205 formed into the gentler circular arc shape than that of the holding protrusion of the comparative example.

The holding top 205 in the first region R1 has the above-described shape. Accordingly, the holding side surface 203 connecting with the holding top 205 is away from the side surface 28 of the member to be housed 2 in the first region R1. A gap distance of the holding side surface 203 away from the side surface 28 of the member to be housed 2 is larger when getting closer to the end portion in the extension direction AR1. Accordingly, as illustrated in FIG. 4A, when the vibration or the collision is not applied to the packaging tray 1 (in a normal state), the first region R1 of the holding side surface 203 and the side surface 28 of the member to be housed 2 do not come into contact with each other.

A side of the holding top 205 in the second region R2, the side facing the side surface 28 of the member to be housed 2, is substantially in parallel to the extension direction AR1. That is, the holding top 205 in the second region R2 is substantially in parallel to the side surface 28 of the member to be housed 2. Accordingly, a length of the holding top 205 in the second region R2 in the intersection direction AR2 is larger than a length of the holding top 205 in the first region R1 in the intersection direction AR2. The holding top 205 in the second region R2 has the above-described shape. Accordingly, in the second region R2, the holding side surface 203 connecting with the holding top 205 comes into contact with the side surface 28 of the member to be housed 2 as illustrated in FIG. 4B. That is, the member to be housed 2 is held by the holding side surface 203 in the second region R2.

The holding protrusion 202 in the first region R1 is made of connection of three surfaces that are the holding side surface 203, the holding end surface 204, and the holding top 205. Accordingly, the holding protrusion 202 in the first region R1 is harder and higher in rigidity than those of the holding protrusion 202 in the second region R2 made of connection of two surfaces that are the holding side surface 203 and the holding top 205. When the first region R1 is not formed into the above-described shape while the holding side surface 203 has a shape not bringing it to be away from the side surface 28 of the member to be housed 2 as different from the first embodiment, the holding side surface 203 and the side surface 28 of the member to be housed 2 come into contact with each other even in the first region R1. In this state, when the vibration or the collision is applied to the packaging tray 1 (in a colliding state), a local stress is exerted on the member to be housed 2 that comes into contact with the first region R1 of the holding side surface 203, or the member to be housed 2 is deformed, and therefore, there is a risk of damage on the member to be housed 2.

On the other hand, in the normal state of the first embodiment, the holding side surface 203 and the side surface 28 of the member to be housed 2 in the first region R1 do not come into contact with each other. In the colliding state thereof, the side surface 28 of the member to be housed 2 deformed by an impact or the like comes into contact with the holding side surface 203 in the first region R1 only for a very short period of time. Therefore, the application of the local stress on the member to be housed 2 and the deformation of the member to be housed 2 in the colliding state are moderated, and the occurrence of the damage on the member to be housed 2 is suppressed.

The above-described first embodiment provides at least one of the following functions and effects.

(1) The shape of the holding protrusion 202 in the first region R1 differs from the shape of the holding protrusion 202 in the second region R2. Therefore, the holding side surface 203 and the side surface 28 of the member to be housed 2 do not always come into contact with each other in the vicinity of the holding end surface 204 that is the end portion of the holding protrusion 202. As a result, the application of the local stress on the member to be housed 2 and the deformation of the member to be housed 2 in the colliding state are moderated, and the occurrence of the damage on the member to be housed 2 is suppressed.

(2) The holding side surface 203 in the first region R1 is further away from the side surface 28 of the member to be housed 2 when getting closer to the end portion in the extension direction AR1. Accordingly, in the normal state, the shape is obtained in which the holding protrusion 202 does not come into contact with the side surface 28 of the member to be housed 2 in the first region R1. As a result, the local stress on the member to be housed 2 and the deformation of the member to be housed 2 in the colliding state are difficult to be applied, and therefore, the cause of the damage on the member to be housed 2 can be reduced.

### Second Embodiment

A packaging tray according to a second embodiment will be described below. In the following description, the same components as those in the first embodiment are respectively denoted with the same reference numerals, and differences from the first embodiment will be mainly described. Points not particularly described are similar to those in the first embodiment.

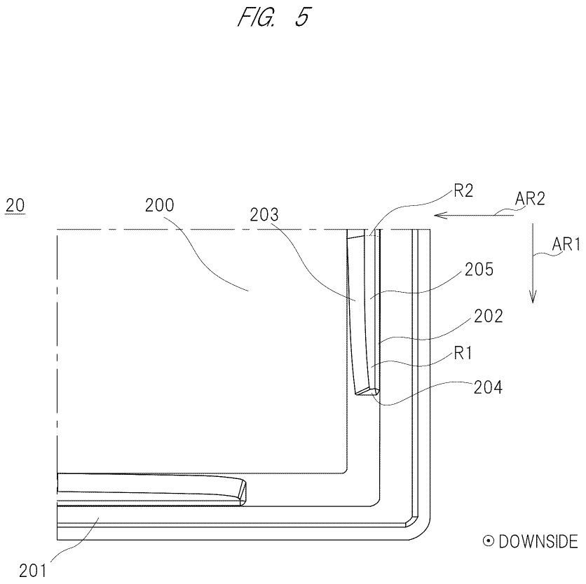

FIG. 5 is an exterior view illustrating an enlarged part of the lower side of the holding part 20 included in the packaging tray 1 according to the second embodiment. In the holding protrusion 202 included in the holding part 20 in the second embodiment, as similar to the first embodiment, a shape of the holding protrusion 202 in the first region R1 differs from a shape of the holding protrusion 202 in the second region R2. Specifically, the holding side surface 203 in the first region R1 has a shape which does not contact with the side surface 28 of the member to be housed 2 in the normal state. That is, in the first region R1, the gap distance of the holding side surface 203 away from the side surface 28 of the member to be housed 2 is larger when getting closer to the end portion in an extension direction AR1. Also in the second embodiment, the holding top 205 in the first region R1 is also formed into the gentle circular arc shape. Specifically, a value of the curve radius of at least a part of the holding top 205 formed into the circular arc shape is larger than a value of the curve radius of the first embodiment to take a value of, for example, nearly 1500 mm. That is, it can be said that the holding protrusion 202 of the second embodiment includes the holding top 205 formed into a circular arc shape gentler than that of the above-described comparative example in which the value of the curve radius is nearly 20 mm to 30 mm.

However, in the second embodiment, the first region R1 is a range from a center to an end portion (the holding end surface 204) of the holding protrusion 202 in the extension direction AR1. In other words, a center portion of the holding protrusion 202 in the extension direction AR1 is the second region R2. Accordingly, in the normal state, the side surface 28 of the member to be housed 2 comes into contact with only a center portion of the holding side surface 203. In the colliding state, the side surface 28 of the member to be housed 2 deformed by an impact or the like comes into contact with the holding side surface 203 in the first region R1 only for a very short period of time. Therefore, as similar to the first embodiment, the application of the local stress on the member to be housed 2 and the deformation of the member to be housed 2 in the colliding state can be moderated, and the occurrence of the damage on the member to be housed 2 is suppressed.

In the above-described second embodiment, the holding side surface 203 in the second region R2 is a center portion of the holding side surface 203 in the extension direction AR1. Accordingly, in the normal state, only the center portion of the holding side surface 203 is contacted. As a result, the functions and effects as similar to the functions and effects resulted from the first embodiment is obtained.

### Third Embodiment

A packaging tray according to a third embodiment will be described below. In the following description, the same components as those in the first embodiment are respectively denoted with the same reference numerals, and differences from the first embodiment will be mainly described. Points not particularly described are similar to those in the first embodiment.

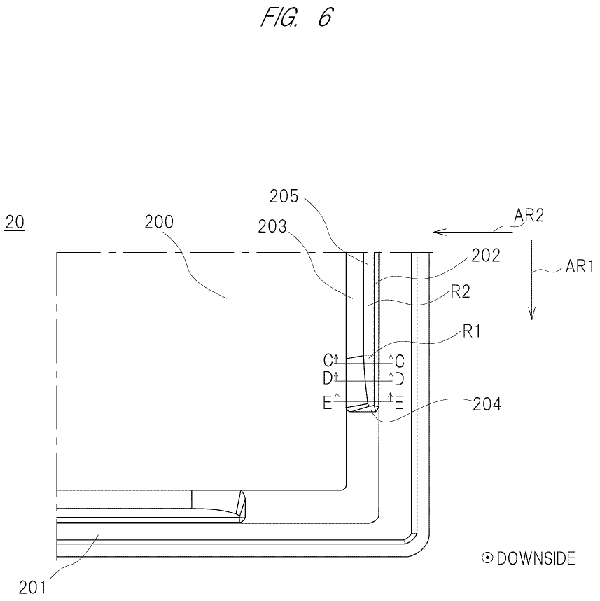

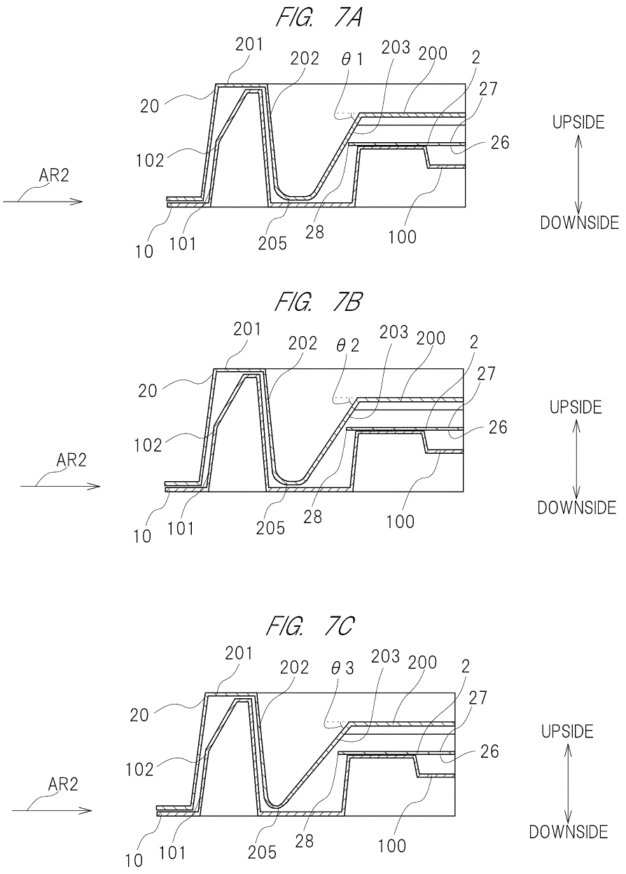

FIG. 6 is an exterior view illustrating an enlarged part of the lower side of the holding part 20 included in the packaging tray 1 according to the third embodiment. FIG. 7 is each cross-sectional view of the holding protrusion 202 illustrated in FIG. 6. FIG. 7A is a cross-sectional view taken along a line C-C illustrated in FIG. 6, FIG. 7B is a cross-sectional view taken along a line D-D illustrated in FIG. 6, and FIG. 7C is a cross-sectional view taken along a line E-E illustrated in FIG. 6.

In the holding protrusion 202 included in the holding part 20 in the third embodiment, as similar to the first embodiment, a shape of the holding protrusion 202 in the first region R1 differs from a shape of the holding protrusion 202 in the second region R2. Specifically, in the first region R1, the holding protrusion 202 formed into a taper shape differs in inclination of the holding side surface 203 for each different position in the extension direction AR1. More particularly, an angle formed by the holding bottom surface 200 and the holding side surface 203 of the holding part 20 gets smaller when getting closer from the vicinity of a boundary between the first region R1 and the second region R2 to the end portion (the holding end surface 204) of the first region R1 in the extension direction AR1. That is, a protrusion angle of the holding protrusion 202 with respect to the holding bottom surface 200 gets smaller when getting closer to the end portion in the extension direction AR1.

As illustrated in FIG. 7A, in the vicinity of the boundary with the second region R2, an angle θ1 formed by the holding bottom surface 200 and the holding side surface 203 is, for example, 60°. As illustrated in FIG. 7C, in the vicinity of the end portion of the first region R1, an angle θ3 formed by the holding bottom surface 200 and the holding side surface 203 is, for example, 45°. As illustrated in FIG. 7B, in the vicinity of an intermediate position between the vicinity of the boundary with the second region R2 and the vicinity of the end portion of the first region R1, an angle θ2 formed by the holding bottom surface 200 and the holding side surface 203 is, for example, 52°. Note that respective values of the angles θ1, θ2, and θ3 are examples, and may take appropriately preferable values depending on the length of the holding protrusion 202 in the extension direction AR1 or the like.

In the first region R1, an angle formed by the holding bottom surface 200 and the holding side surface 203 differs for each different position in the extension n direction AR1. Accordingly, a side of the holding top 205 connecting with the holding side surface 203, the side facing the side surface 28 of the member to be housed 2, is formed into a circular arc shape. That is, the holding top 205 of the third embodiment in the first region R1 has the similar shape to the shape of the holding top 205 of the first embodiment in the first region R1.

Accordingly, also in the third embodiment, in the normal state, the holding side surface 203 in the first region R1 and the side surface 28 of the member to be housed 2 do not come into contact with each other. In the colliding state, the side surface 28 of the member to be housed 2 deformed by an impact comes into contact with the holding side surface 203 in the first region R1 only for a very short period of time. Therefore, the application of the local stress on the member to be housed 2 and the deformation of the member to be housed 2 in the colliding state are moderated, and the occurrence of the damage on the member to be housed 2 is suppressed.

According to the above-described third embodiment, the protrusion angle of the holding protrusion 202 with respect to the holding bottom surface 200 gets smaller when getting closer to the end portion in the extension direction AR1. Accordingly, in the first region R1 in the normal state, the shape is obtained in which the holding protrusion 202 does not come into contact with the side surface 28 of the member to be housed 2. As a result, the similar functions and effects to the functions and effects provided by the above-described first embodiment are provided.

### Fourth Embodiment

A packaging tray according to a fourth embodiment will be described below. In the following description, the same components as those in the first embodiment are respectively denoted with the same reference numerals, and differences from the first embodiment will be mainly described. Points not particularly described are similar to those in the first embodiment.

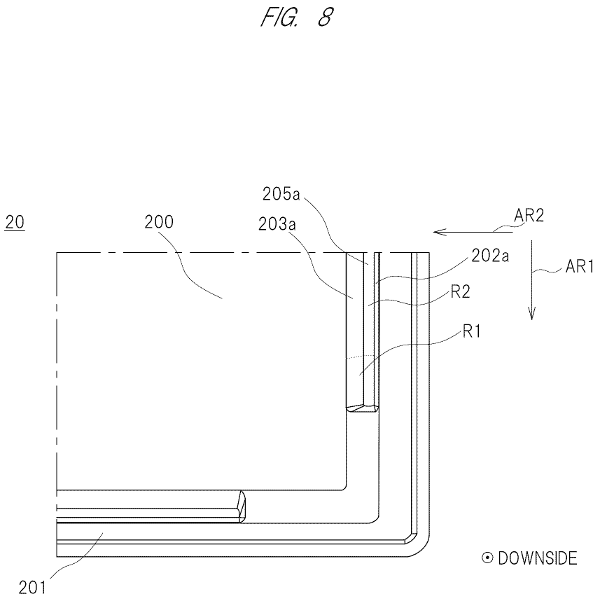

FIG. 8 is an exterior view illustrating an enlarged part of the lower side of the holding part 20 included in the packaging tray 1 according to the fourth embodiment. A holding protrusion 202a included in the holding part 20 of the fourth embodiment also has a holding side surface 203a that comes into contact with a side surface of the member to be housed 2 even in the first region R1. Specifically, in the first region R1, a side of a holding top 205a of the holding protrusion 202a, the side facing the side surface 28 of the member to be housed 2, is not formed into a circular arc shape but extends in substantially parallel to the extension direction AR1 as different from the first to third embodiments. Accordingly, the side surface 28 of the member to be housed 2 and the holding side surface 203a come into contact with each other in both the normal state and the colliding state.

However, the holding side surface 203a in the first region R1 is thinner (smaller in thickness) than the holding side surface 203a in the second region R2. That is, the holding protrusion 202a in the first region R1 is softer (lower in rigidity) than the holing protrusion 202a in the second region R2. Accordingly, concentration of a stress on the first region R1 of the holding protrusion 202a in the colliding state is suppressed. As a result, the concentration of the local stress on the member to be housed 2 and the deformation of the member to be housed 2 in the colliding state can be moderated, and the occurrence of the damage on the member to be housed 2 is suppressed.

The above-described fourth embodiment provides at least one of the following functions and effects.

(3) The holding protrusion 202a in the first region R1 has a lower rigidity than that of the holding protrusion 202a in the second region R2. Accordingly, the concentration of the stress on the first region R1 of the holding protrusion 202a in the colliding state is suppressed. As a result, the application of the stress on the member to be housed 2 and the deformation of the member to be housed 2 can be moderated, and the occurrence of the damage on the member to be housed 2 is suppressed.

(4) The holding side surface 203a in the first region R1 is thinner than the holding side surface 203a in the second region R2. This can result in a state in which the rigidity of the holding protrusion 202a in the first region R1 is lower than the rigidity of the holding protrusion 202a in the second region R2. As a result, the application of the stress on the member to be housed 2 and the deformation of the member to be housed 2 in the colliding state can be moderated, and the cause of the damage on the member to be housed 2 can be reduced.

### Fifth Embodiment

A packaging tray according to a fifth embodiment will be described below. In the following description, the same components as those in the fourth embodiment are respectively denoted with the same reference numerals, and differences from the fourth embodiment will be mainly described. Points not particularly described are similar to those in the fourth embodiment.

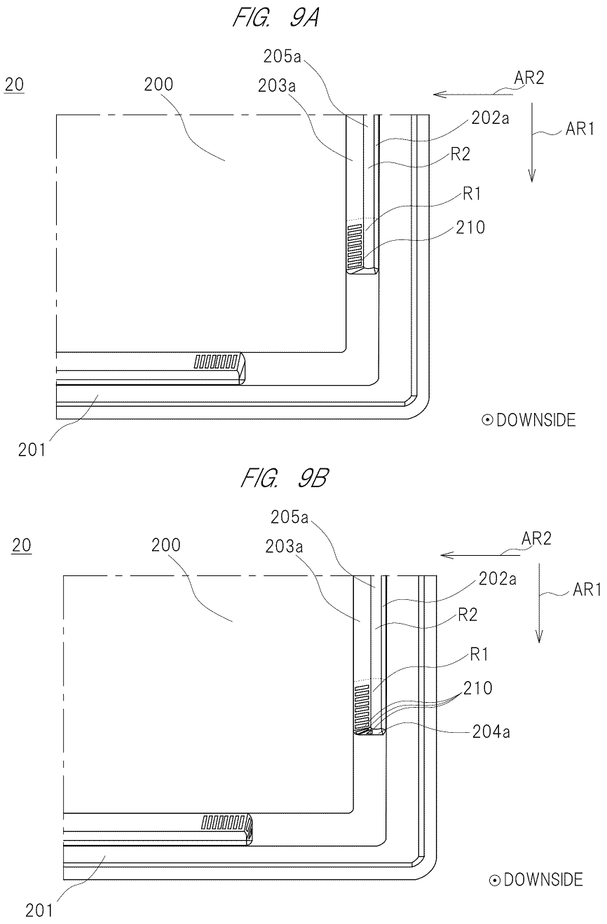

FIG. 9A is an exterior view illustrating an enlarged part of the lower side of the holding part 20 included in the packaging tray 1 according to the fifth embodiment. As similar to the fourth embodiment, the holding protrusion 202a included in the holding part 20 of the fifth embodiment also has the holding side surface 203a that comes into contact with the side surface 28 of the member to be housed 2 even in the first region R1. As different from the fourth embodiment, the respective thicknesses of the holding side surfaces 203a in the first region R1 and the second region R2 are substantially the same.

As similar embodiment, in the holding protrusion 202a included in the holding part 20 in the fifth embodiment, the rigidity of the holding protrusion 202a in the first region R1 is lower than that of the holding protrusion 202a in the second region R2. Specifically, in the first region R1, a plurality of slit-shaped openings 210 are formed on the holding side surface 203a. Each of the openings 210 penetrate through the holding side surface 203a, and extends in a direction (the up-down direction) intersecting the extension direction AR1. The plurality of openings 210 having the above-described shape are formed side by side in the extension direction AR1. Note that the openings 210 may extend in the extension direction AR1. In this case, the plurality of openings 210 may be formed side by side in the up-down direction.

According to the above-described fifth embodiment, the plurality of openings 210 are formed in the first region R1, and therefore, the rigidity of the holding side surface 203a in the first region R1 is lowered, and the concentration of the stress on the first region R1 of the holding protrusion 202a in the colliding state is suppressed. As a result, as similar to the function and effects (3) provided by the fourth embodiment, the stress on the member to be housed 2 and the deformation of the member to be housed 2 in the colliding state can be moderated, and the occurrence of the damage on the member to be housed 2 is suppressed.

### Sixth Embodiment

A packaging tray according to a sixth embodiment will be described below. In the following description, the same components as those in the fourth embodiment are respectively denoted with the same reference numerals, and differences from the fourth embodiment will be mainly described. Points not particularly described are similar to those in the fourth embodiment.

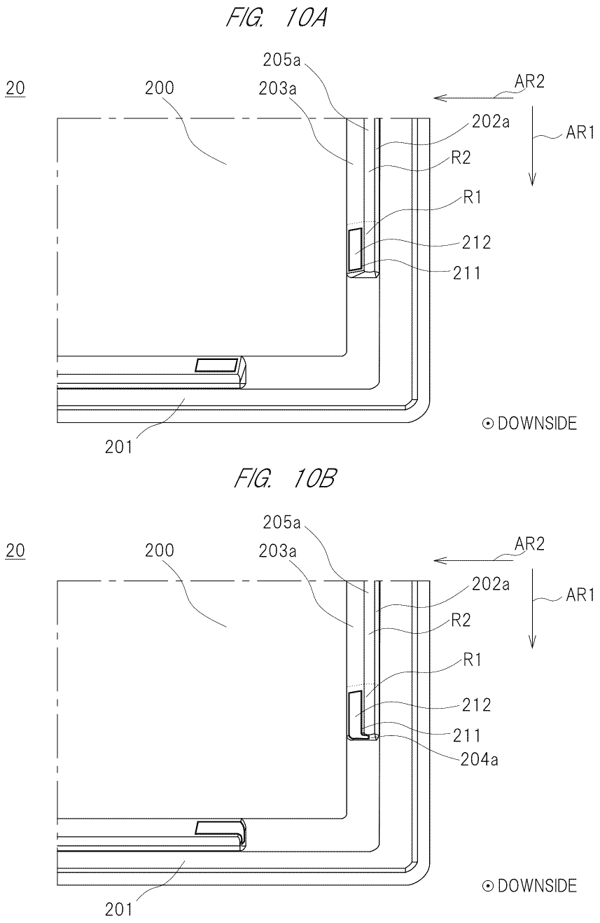

FIG. 10A is an exterior view illustrating an enlarged part of the lower side of the holding part 20 included in the packaging tray 1 according to the sixth embodiment. As similar to the fourth embodiment, the holding protrusion 202a included in the holding part 20 of the sixth embodiment also has the holding side surface 203a that comes into contact with the side surface of the member to be housed 2 even in the first region R1. As different from the fourth embodiment, the respective thicknesses of the holding side surfaces 203a in the first region R1 and the second region R2 are substantially the same.

As similar to the fourth embodiment, in the holding protrusion 202a included in the holding part 20 in the sixth embodiment, the rigidity of the holding protrusion 202a in the first region R1 is lower than that of the holding protrusion 202a in the second region R2. Specifically, for example, a rectangular-shaped attachment opening 211 is formed on the holding side surface 203a in the first region R1. The attachment opening 211 is an opening to which a buffer member 212 made of a different material from that of the holding part 20 is to be attached. The buffer member 212 is manufactured using a material such as a urethane foam or a nonwoven fabric that is softer (lower in rigidity) than a material of the holding part 20. The buffer member 212 is bonded and fixed to the attachment opening 211 by an adhesive or the like. In this case, the buffer member 212 may be attached so as to be substantially on the same surface as the holding side surface 203a, i.e., so that the buffer member 212 does not further protrude toward the side surface 28 of the member to be housed 2 than the holding side surface 203a.

According to the above-described sixth embodiment, the buffer member 212 is provided to the attachment opening 211 formed on the holding side surface 203a in the first region R1, and therefore, the rigidity of the holding side surface 203a in the first region R1 is lowered. Accordingly, the concentration of the stress on the first region R1 of the holding protrusion 202a in the colliding state is suppressed. As a result, as similar to the function and effects (3) provided by the fourth embodiment, the stress on the member to be housed 2 and the deformation of the member to be housed 2 in the colliding state can be moderated, and the occurrence of the damage on the member to be housed 2 is suppressed.

Note that the holding side surface 203a in the first region R1 may be made of a different material from that of the holding side surface 203a in the second region R2 instead of the attachment of the buffer member 212 to the attachment opening 211 formed on the holding side surface 203a in the first region R1. In this case, the holding side surface 203a in the first region R1 is made of a material that is softer (lower in rigidity) than the material of the holing side surface 203a in the second region R2. Specifically, a member made of, for example, a similar material to the above-described material of the buffer member 212 is monolithically formed by, for example, insert molding or the like at a position of the formation of the attachment opening 211 on the holding side surface 203a in the first region R1. Accordingly, the stress on the member to be housed 2 and the deformation of the member to be housed 2 in the colliding state can be moderated. As a result, as similar to the function and effects (3) provided by the fourth embodiment, the occurrence of the damage on the member to be housed 2 is suppressed.

### Seventh Embodiment

A packaging tray according to a seventh embodiment will be described below. In the following description, the same components as those in the first embodiment are respectively denoted with the same reference numerals, and differences from the first embodiment will be mainly described. Points not particularly described are similar to those in the first embodiment.

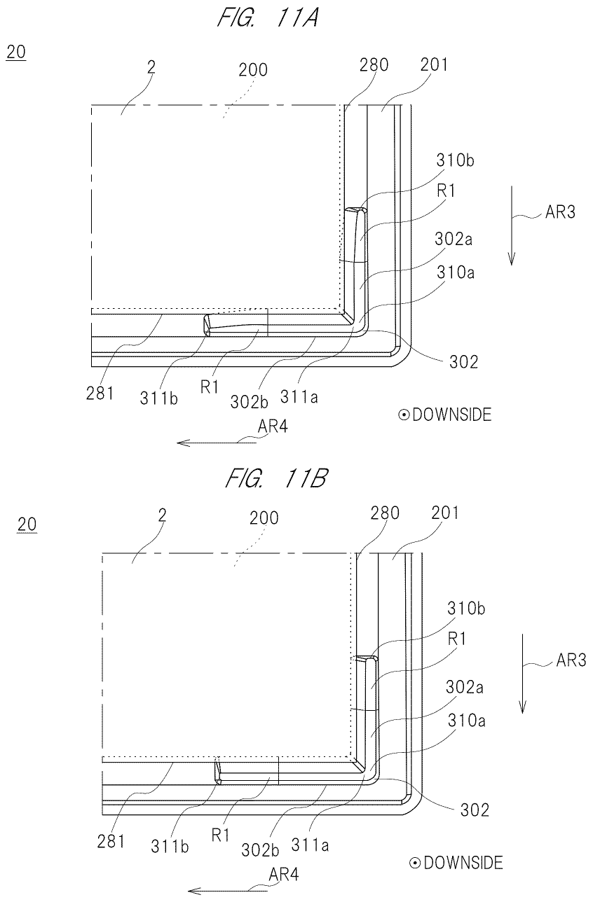

FIG. 11A is an exterior view illustrating an enlarged part of the lower side of the holding part 20 included in the packaging tray 1 according to the seventh embodiment and the member to be housed 2 held by the holding part 20.

The holding part 20 of the seventh embodiment includes holding protrusions 302 at the vicinities of four corners of the member to be housed 2. Note that FIG. 11A illustrates the holding part 20 close to one of the four corners of the member to be housed 2.

The holding protrusion 302 includes a first extension 302a and a second extension 302b. The first extension 302a extends in a first extension direction AR3 in which a first side surface 280 of the member to be housed 2 extends. The second extension 302b extends in a second extension direction AR4 in which a second side surface 281 of the member to be housed 2 extends. The first extension direction AR3 and the second extension direction AR4 intersect each other. More particularly, the first extension direction AR3 and the second extension direction AR4 are perpendicular to each other. In other words, the first extension 302a and the second extension 302b extend in respective directions intersecting each other, more particularly in directions perpendicular to each other.

One-side end portion 310a of the first extension 302a connects with one-side end portion 311a of the second extension 302b. Specifically, the one-side end portion 310a of the first extension 302a is at vicinity of a corner at which the first side surface 280 of the member to be housed 2 connects with the second side surface 281. The one-side end portion 311a of the second extension 302b is at vicinity of a corner at which the second side surface 281 and the first side surface 280 of the member to be housed 2 connect with each other. Therefore, the holding protrusion 302 is formed on the outer periphery of the member to be housed 2 along the first side surface 280 and the second side surface 281 at the vicinity of the corner of the member to be housed 2.

A length of the first extension 302a extending in the first extension direction AR3 is smaller than a length of the first side surface 280 of the member to be housed 2. The first region R1 similar to that of the above-described first embodiment is formed in the vicinity of the other-side end portion 310b of the first extension 302a. Specifically, a holding side surface 203 on the end portion 310b of the first extension 302a is away from the first side surface 280 of the member to be housed 2, the end portion 310b being in a direction farther away from the corner between the first side surface 280 and the second side surface 281 of the member to be housed 2. However, in the vicinity of the one-side end portion 310a of the first extension 302a, the holding side surface 203 comes into contact with the first side surface 280 of the member to be housed 2. That is, the other-side end portion 310b of the first extension 302a differs in shape from the one-side end portion 310a of the first extension 302a.

Similarly, a length of the second extension 302b extending in the second extension direction AR4 is smaller than a length of the second side surface 281 of the member to be housed 2. The first region R1 similar to that of the above-described first embodiment is formed in the vicinity of the other-side end portion 311b of the second extension 302ab. Specifically, a holding side surface 203 in the vicinity of the end portion 311b of the second extension 302b is away from the second side surface 281 of the member to be housed 2, the end portion 311b being in a direction farther away from the corner between the first side surface 280 and the second side surface 281 of the member to be housed 2. However, in the vicinity of the one-side end portion 311a of the second extension 302b, the holding side surface 203 comes into contact with the second side surface 281 of the member to be housed 2. That is, the other-side end portion 311b of the second extension 302b differs in shape from the one-side end portion 311a of the second extension 302b.

The holding protrusions 302 are respectively formed in the vicinities of the four corners of the member to be housed 2, and therefore, the attachment recesses 101 of the housing part 10 are also respectively formed in the vicinities of the four corners of the member to be housed 2. Therefore, when the holding part 20 is arranged above the housing part 10, the holding protrusions 302 are respectively housed in the attachment recesses 101 in the housing part 10.

According to the above-described seventh embodiment, the holding protrusion 302 has the above-described shape. Accordingly, in the colliding state in which the vibration or the collision is applied to the packaging tray 1, the end portion that is a cause of the concentration of the stress on the member to be housed 2 and the deformation of the member to be housed 2 is not formed in the holding protrusion 302. Accordingly, the stress on the member to be housed 2 and the deformation of the member to be housed 2 in the colliding state can be moderated, and therefore, the occurrence of the damage on the member to be housed 2 is suppressed. That is, the functions and effects similar to the functions and effects provided by the above-described first embodiment are provided.

Note that the present invention is not limited to the formation of the first region R1 similar to that of the first embodiment in each of the vicinities of the other-side end portions 310b and 311b of the first extension 302a and the second extension 302b. The first region R1 similar to the first region R1 of the second or third embodiment may be formed in each of the vicinities of the other-side end portions 310b and 311b of the first extension 302a and the second extension 302b. As a result, the functions and effects similar to the functions and or third effects provided by the above-described second embodiment are provided.

The first region R1 similar to the first region R1 of the fourth, fifth, or sixth embodiment may be formed in each of the vicinities of the other-side end portions 310b and 311b of the first extension 302a and the second extension 302b. In other words, the other-side end portion 310b of the first extension 302a and the other-side end portion 311b of the second extension 302b may be lower in rigidity than the one-side end portion 310a of the first extension 302a and the one-side end portion 311a of the second extension 302b. FIG. 11B illustrates a case where the respective thicknesses of the vicinities of the other-side end portions 310b and 311b of the first extension 302a and the second extension 302b are smaller than the respective thicknesses of the vicinities of the one-side end portions 310a and 311a of the first extension 302a and the second extension 302b. As a result, the functions and effects similar to the functions and effects provided by the above-described fourth, fifth or sixth embodiment are provided.

Between the holding protrusion 302 provided at the one corner of the member to be housed 2 and the holding protrusion 302 provided at the other corner thereof, the holding protrusions 202 and 202a described in the first to sixth embodiments may be each formed depending on the respective lengths of the first side surface 280 and the second side surface 281 of the member to be housed 2.

### Eighth Embodiment

A packaging tray according to an eighth embodiment will be described below. In the following description, the same components as those in the first embodiment are respectively denoted with the same reference numerals, and differences from the first embodiment will be mainly described. Points not particularly described are similar to those in the first embodiment.

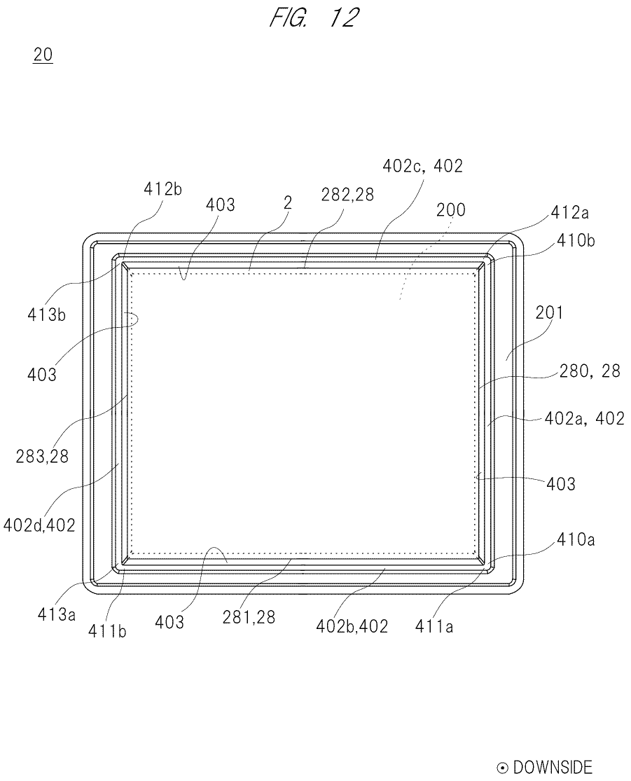

FIG. 12 is an exterior view illustrating the lower side of the holding part 20 included in the packaging tray 1 according to the eighth embodiment and the member to be housed 2 held by the holding part 20.

The holding part 20 of the eighth embodiment includes a holding protrusion 402. The holding protrusion 402 is formed along the respective outer peripheries of four side surfaces (a first side surface 280, a second side surface 281, a third side surface 282, and a fourth side surface 283) of the member to be housed 2. The holding protrusion 402 is formed to surround an entire range of the outer peripheries of the member to be housed 2.

Specifically, the holding protrusion 402 includes a first protrusion 402a, a second protrusion 402b, a third protrusion 402c, and a fourth protrusion 402d. The first protrusion 402a extends along the first side surface 280 of the member to be housed 2. The second protrusion 402b extends along the second side surface 281 of the member to be housed 2. The third protrusion 402c extends along the third side surface 282 of the member to be housed 2. The fourth protrusion 402d extends along the fourth side surface 283 of the member to be housed 2.

One-side end portion 410a of the first protrusion 402a connects with one-side end portion 411a of the second protrusion 402b, and the other-side end portion 410b of the first protrusion 402a connects with one-side end portion 412a of the third protrusion 402c. One-side end portion 413a of the fourth protrusion 402d connects with the other-side end portion 411b of the second protrusion 402b, and the other-side end portion 413b of the fourth protrusion 402d connects with the other-side end portion 412b of the third protrusion 402c. In other words, the first protrusion 402a, the second protrusion 402b, the third protrusion 402c, and the fourth protrusion 402d connect with one another, respectively, at four corners of the member to be housed 2, and therefore, the outer peripheries of the member to be housed 2 are surrounded by the holding protrusion 402.

Note that the first region R1 described in each of the above-described embodiments is not formed on the respective holding side surfaces 403 of the first protrusion 402a, the second protrusion 402b, the third protrusion 402c and the fourth protrusion 402d. That is, the holding side surfaces 403 comes into contact with the side surface 28 of the member to be housed 2 in the entire range in which the first protrusion 402a, the second protrusion 402b, the third protrusion 402c, and the fourth protrusion 402d extend.

According to the above-described eighth embodiment, the holding protrusion 402 has the above-described shape. Accordingly, the holding side surfaces 403 comes into contact with the entire region of the side surface 28 of the member to be housed 2. That is, an end portion that is a cause of the concentration of the stress on the member to be housed 2 and the deformation of the member to be housed 2 in the colliding state in which the vibration or the collision are applied to the packaging tray 1 is not formed in the holding protrusion 402. Accordingly, the stress on the member to be housed 2 and the deformation of the member to be housed 2 in the colliding state can be moderated, and therefore, the occurrence of the damage on the member to be housed 2 is suppressed.

In the scope of the idea of the present invention, various modification examples and alteration examples could have been easily anticipated by those who are skilled in the art, and it would be understood that these various modification examples and alteration examples are within the scope of the present invention. For example, the ones obtained by appropriate addition, removal, or design-change of the components to/from/into each of the above-described embodiments by those who are skilled in the art or obtained by addition, omitting, or condition-change of the step to/from/into each of the above-described embodiments are also within the scope of the present invention as long as they include the idea of the present invention.

For example, the present invention is not limited to the formation of the opening 210 on the holding side surface 203a as described in the fifth embodiment, and the opening 210 may be also formed on the holding end surface 204a. FIG. 9B illustrates an enlarged part of the lower side of the holding part 20 in this case. As illustrated in FIG. 9B, the opening 210 formed on the holding end surface 204a also extends in the up-down direction as similar to the opening 210 formed on the holding side surface 203a. As a result, the rigidity of the holding protrusion 202a in the first region R1 is made lower.

The present invention is not limited to the formation of the attachment opening 211 on the holding side surface 203a as described in the sixth embodiment, and the attachment opening 211 may be formed on the holding side surface 203a and the holding end surface 204a. FIG. 10B illustrates an enlarged part of the lower side of the holding part 20 in this case. As illustrated in FIG. 10B, the attachment opening 211 is formed from the holding side surface 203a to the holding end surface 204a. As a result, the rigidity of the holding protrusion 202a in the first region R1 is made lower.

What is claimed is:

1. A packaging tray comprising:
a housing part housing a flat-plate-shaped member to be housed, including a glass plate member;
a holding part covering the member to be housed and the housing part to hold the member to be housed in a direction different from a direction of the housing part; and
a plurality of protrusions provided in the holding part, protruding toward the housing part, and each extending along a side surface of the member to be housed in an extension direction in which the side surface extends,
wherein the protrusion includes a first region between its end surface and center in the extension direction and a second region different from the first region, and
a shape of the protrusion in the first region differs from a shape of the protrusion in the second region.

2. The packaging tray according to claim 1,
wherein the protrusion has a taper-shaped holding side surface coming into contact with the side surface of the member to be housed to hold the member to be housed in the extension direction,
a length of the holding side surface is smaller than a length of the side surface of the member to be housed in the extension direction, and
the holding side surface in the first region is further away from the side surface of the member to be housed when getting closer to an end portion in the extension direction.

3. The packaging tray according to claim 2,
wherein the holding side surface in the second region is at a center of the holding side surface in the extension direction.

4. The packaging tray according to claim 1,
wherein the holding part has a holding bottom surface facing a surface of the member to be housed when the holding part holds the member to be housed, and
in the first region, a protrusion angle of the protrusion with respect to the holding bottom surface gets smaller when getting closer to an end portion in the extension direction.

5. The packaging tray according to claim 1,
wherein the protrusion includes a first extension extending along a first side surface of the member to be housed and a a second extension extending along second side surface intersecting the first side surface of the member to be housed,
one-side end portion of the first extension connects with one-side end portion of the second extension, and
the other-side end portion of the first extension and the other-side end portion of the second extension differ in shape from the one-side end portion of the first extension and the one-side end portion of the second extension.

6. The packaging tray according to claim 2,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension differ in shape from the one-side end portion of the first extension and the one-side end portion of the second extension.

7. The packaging tray according to claim 3,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension differ in shape from the one-side end portion of the first extension and the one-side end portion of the second extension.

8. The packaging tray according to claim 4,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension differ in shape from the one-side end portion of the first extension and the one-side end portion of the second extension.

9. A packaging tray comprising:
a housing part housing a flat-plate-shaped member to be housed, including a glass plate member;
a holding part covering the member to be housed and the housing part to hold the member to be housed in a direction different from a direction of the housing part; and
a plurality of protrusions provided in the holding part, protruding toward the housing part, and each extending along a side surface of the member to be housed in an extension direction in which the side surface extends,
wherein the protrusion includes a first region between its end surface and center in the extension direction and a second region different from the first region, and
the protrusion in the first region has a lower rigidity than a rigidity of the protrusion in the second region.

10. The packaging tray according to claim 9,
wherein the protrusion has a taper-shaped holding side surface coming into contact with the side surface of the member to be housed to hold the member to be housed in the extension direction,
a length of the holding side surface is smaller than a length of the side surface of the member to be housed in the extension direction, and
a thickness of the holding side surface in the first region is smaller than a thickness of the holding side surface in the second region.

11. The packaging tray according to claim 9,
wherein the protrusion has a taper-shaped holding side surface coming into contact with the side surface of the member to be housed to hold the member to be housed in the extension direction,
a length of the holding side surface is smaller than a length of the side surface of the member to be housed in the extension direction, and
a plurality of slits are formed on the holding side surface in the first region.

12. The packaging tray according to claim 9,
wherein the protrusion has a taper-shaped holding side surface coming into contact with the side surface of the member to be housed to hold the member to be housed in the extension direction,
a length of the holding side surface is smaller than a length of the side surface of the member to be housed in the extension direction, and
the holding side surface in the first region is made of a member softer than a material of the holding side surface in the second region.

13. The packaging tray according to claim 12,
wherein the soft member is attached to an opening formed on the holding side surface in the first region.

14. The packaging tray according to claim 9,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension are lower in rigidity than the one-side end portion of the first extension and the one-side end portion of the second extension.

15. The packaging tray according to claim 10,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension are lower in rigidity than the one-side end portion of the first extension and the one-side end portion of the second extension.

16. The packaging tray according to claim 11,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension are lower in rigidity than the one-side end portion of the first extension and the one-side end portion of the second extension.

17. The packaging tray according to claim 12,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension are lower in rigidity than the one-side end portion of the first extension and the one-side end portion of the second extension.

18. The packaging tray according to claim 13,
wherein the protrusion includes a first extension extending along a first side surface of the member to be housed and a second extension extending along a second side surface intersecting the first side surface of the member to be housed,
one-side end portion of the first extension connects with one-side end portion of the second extension, and
the other-side end portion of the first extension and the other-side end portion of the second extension are lower in rigidity than the one-side end portion of the first extension and the one-side end portion of the second extension.

19. A packaging tray comprising:
a housing part housing a flat-plate-shaped member to be housed, including a glass plate member;
a holding part covering the member to be housed and the housing part to hold the member to be housed in a direction different from a direction of the housing part; and
a protrusion provided in the holding part, protruding toward the housing part, and surrounding an entire range of respective outer peripheries of side surfaces of the member to be housed,
wherein the protrusion has a taper-shaped holding side surface holding the member to be housed while coming into contact with the side surface of the member to be housed.
